(19) United States
(12) Patent Application Publication
(10) Pub. No.: US 2021/0405714 A1
(43) Pub. Date: Dec. 30, 2021

(54) CHIP ON FILM ASSEMBLY AND DISPLAY PANEL ASSEMBLY

(71) Applicant: TCL China Star Optoelectronics Technology Co., Ltd., Shenzhen, Guangdong (CN)

(72) Inventor: Xiaoli Fu, Shenzhen Guangdong (CN)

(21) Appl. No.: 16/617,270

(22) PCT Filed: Oct. 29, 2019
(86) PCT No.: PCT/CN2019/114000

§ 371 Date: Nov. 26, 2019

(30) Foreign Application Priority Data
Aug. 9, 2019 (CN) 201910732208.5

(51) Int. Cl. G06F 1/18; G09G 3/20

(52) U.S. Cl. CPC G06F 1/189; G09G 2300/0408; G09G 3/20

(57) ABSTRACT

The chip on film assembly provided in the present disclosure comprises a substrate which includes a first auxiliary area, a second auxiliary area, and a chip on film area. The first auxiliary area, the chip on film area, and the second auxiliary area are disposed in sequence along a first direction. A plurality of signal wirings are disposed on one side of the chip on film area adjacent to the first auxiliary area and one side of the chip on film area that is adjacent to the second auxiliary area; the first auxiliary area and the second auxiliary area are used to prevent the signal wirings from breaking.

### FIELD OF INVENTION

The present disclosure relates to the field of display technologies, and more particularly to a chip on film assembly and a display panel assembly.

### BACKGROUND OF INVENTION

In current technology, when a chip on film assembly is used to bond a display panel and a circuit board, an edge of one side of the chip on film assembly that is adjacent to a display panel is easy to peel off, causing signal lines broken, thereby making the display panel display abnormally.

An object of an embodiment of the present disclosure is to provide a chip on film assembly and a display panel assembly that could solve the technical problem of an edge on one side of the chip on film assembly adjacent to display panels easy to peel off, causing signal lines broken, thereby making display panels have abnormal display.

### SUMMARY OF INVENTION

An embodiment of the present disclosure provides a chip on film assembly. The chip on film assembly comprises a substrate, wherein the substrate comprises a first auxiliary area, a second auxiliary area, and a chip on film area disposed between the first auxiliary area and the second auxiliary area; the first auxiliary area, the chip on film area, and the second auxiliary area are disposed in sequence along a first direction;

wherein a plurality of signal wirings are disposed on one side of the chip on film area adjacent to the first auxiliary area and one side of the chip on film area that is adjacent to the second auxiliary area; the first auxiliary area and the second auxiliary area are used to prevent the signal wirings from breaking;

a width of the first auxiliary area along the first direction is equal to a width of the second auxiliary area along the first direction; and a material of the substrate is a flexible material.

In an embodiment of the present disclosure, the substrate is provided with a first end part and a second end part opposite to the first end part in a second direction, and the first direction is perpendicular to the second direction; the first end part is bonded to a display panel and is electrically connected to the display panel; the second end part is bonded to a circuit board and is electrically connected to the circuit board.

In an embodiment of the present disclosure, the first auxiliary area and the second auxiliary area are provided with a plurality of first binding points, and the first binding points are disposed adjacent to the first end part and bonded to the display panel.

In an embodiment of the present disclosure, the first binding points are arranged at intervals along the first direction.

In an embodiment of the present disclosure, the chip on film area is provided with a plurality of second binding points and third binding points, the second binding points are disposed adjacent to the first end part and bonded to the display panel, and the third binding points are disposed adjacent to the second end part and bonded to the circuit board.

In an embodiment of the present disclosure, the first binding points and the display panel are idly connected, the second binding points and the display panel are electrically connected, and the third binding points and the circuit board are electrically connected.

In an embodiment of the present disclosure, the width of the first auxiliary area along the first direction and the width of the second auxiliary area along the first direction range from 0.4 cm to 0.7 cm.

An embodiment of the present disclosure further provides a chip on film assembly. The chip on film assembly comprises a substrate, wherein the substrate comprises a first auxiliary area, a second auxiliary area, and a chip on film area disposed between the first auxiliary area and the second auxiliary area; the first auxiliary area, the chip on film area, and the second auxiliary area are disposed in sequence along a first direction;

wherein a plurality of signal wirings are disposed on one side of the chip on film area adjacent to the first auxiliary area and one side of the chip on film area that is adjacent to the second auxiliary area; the first auxiliary area and the second auxiliary area are used to prevent the signal wirings from breaking.

In an embodiment of the present disclosure, the substrate is provided with a first end part and a second end part opposite to the first end part in a second direction, and the first direction is perpendicular to the second direction; the first end part is bonded to a display panel and is electrically connected to the display panel; the second end part is bonded to a circuit board and is electrically connected to the circuit board.

In an embodiment of the present disclosure, the first auxiliary area and the second auxiliary area are provided with a plurality of first binding points, and the first binding points are disposed adjacent to the first end part and bonded to the display panel.

In an embodiment of the present disclosure, the first binding points are arranged at intervals along the first direction.

In an embodiment of the present disclosure, the chip on film area is provided with a plurality of second binding points and third binding points, the second binding points are disposed adjacent to the first end part and bonded to the display panel, and the third binding points are disposed adjacent to the second end part and bonded to the circuit board.

In an embodiment of the present disclosure, the first binding points and the display panel are idly connected, the second binding points and the display panel are electrically connected, and the third binding points and the circuit board are electrically connected.

In an embodiment of the present disclosure, the width of the first auxiliary area along the first direction and the width of the second auxiliary area along the first direction range from 0.4 cm to 0.7 cm.

In an embodiment of the present disclosure, a width of the first auxiliary area along the first direction is equal to a width of the second auxiliary area along the first direction.

In an embodiment of the present disclosure, a material of the substrate is a flexible material.

An embodiment of the present disclosure further provides a display panel assembly. The display panel assembly comprises a chip on film assembly, the chip on film assembly comprises: a substrate, wherein the substrate comprises a first auxiliary area, a second auxiliary area, and a chip on film area disposed between the first auxiliary area and the second auxiliary area; the first auxiliary area, the chip on film area, and the second auxiliary area are disposed in sequence along a first direction;

wherein a plurality of signal wirings are disposed on one side of the chip on film area adjacent to the first auxiliary area and one side of the chip on film area that is adjacent to the second auxiliary area; the first auxiliary area and the second auxiliary area are used to prevent the signal wirings from breaking.

In an embodiment of the present disclosure, the substrate is provided with a first end part and a second end part opposite to the first end part in a second direction, and the first direction is perpendicular to the second direction; the first end part is bonded to a display panel and is electrically connected to the display panel; the second end part is bonded to a circuit board and is electrically connected to the circuit board.

In an embodiment of the present disclosure, the first auxiliary area and the second auxiliary area are provided with a plurality of first binding points, and the first binding points are disposed adjacent to the first end part and bonded to the display panel.

In an embodiment of the present disclosure, the first binding points are arranged at intervals along the first direction.

An embodiment of the present disclosure provides the chip on film assembly and the display panel assembly by disposing the first auxiliary area and the second auxiliary area on both sides of the chip on film area that prevents an edge of the chip on film to peel off and then to cause signal lines of the chip on film area broken, thereby improving product yield and display quality.

### DESCRIPTION OF DRAWINGS

The accompanying figures to be used in the description of embodiments of the present disclosure will be described in brief to more clearly illustrate the technical solutions of the embodiments. The accompanying figures described below are only part of the embodiments of the present disclosure, from which those skilled in the art can derive further figures without making any inventive efforts.

FIG. 1 is a first schematic structural diagram of a chip on film assembly according to an embodiment of the present disclosure.

FIG. 2 is a second schematic structural diagram of a chip on film assembly according to an embodiment of the present disclosure.

FIG. 3 is a schematic structural diagram of a display panel assembly according to an embodiment of the present disclosure.

### DETAILED DESCRIPTION OF PREFERRED EMBODIMENTS

The embodiments of the present disclosure are described in detail hereinafter. Examples of the described embodiments are given in the accompanying drawings. The specific embodiments described with reference to the attached drawings are all exemplary and are intended to illustrate and interpret the present disclosure. Based on the embodiments in the present disclosure, all other embodiments obtained by those skilled in the art without creative efforts are within the scope of the present disclosure.

In the description of the present disclosure, it should be noted that, terms such as “first” and “second” are used herein for purposes of description and are not intended to indicate or imply relative importance or implicitly indicating the number of technical features indicated. Thus, features limited by “first” and “second” are intended to indicate or imply inclusion of one or more than one of these features. In the description of the present disclosure, “a plurality of” relates to two or more than two, unless otherwise specified.

Referring to FIG. 1, FIG. 1 is a first schematic structural diagram of a chip on film assembly according to an embodiment of the present disclosure. As shown in FIG. 1, the chip on film assembly 10 comprises a substrate 100, wherein the substrate 100 comprises a first auxiliary area 101, a second auxiliary area 102, and a chip on film area 103 disposed between the first auxiliary area 101 and the second auxiliary area 102, and the first auxiliary area 101, the chip on film area 103, and the second auxiliary area 102 are disposed in sequence along a first direction. It should be noted that, in the embodiment of the present disclosure, the first direction is not limited, it can be a horizontal direction, and it can be a vertical direction.

A material of the substrate 100 is a flexible material. Specifically, the substrate 100 is provided with a first end part 110 and a second end part 120 disposed opposite to the first end part 110. Wherein a second direction is disposed perpendicularly to the first direction. In an embodiment of the present disclosure, when the chip on film assembly 10 is used, the first end part 110 is bonded to the display panel (not shown in the figure) and is electrically connected to the display panel. The second end part 120 is bonded to the circuit board (not shown in the figure) and is electrically connected to the circuit board.

Wherein, the chip on film area 103 is provided with a plurality of second binding points 123 and third binding points 133, the second binding points 123 are disposed adjacent to the first end part 110, and the third binding points 133 are disposed adjacent to the second end part 120. In an embodiment of the present disclosure, when the chip on film assembly 10 is used, the first end part 110 is bonded to the display panel through the plurality of second binding points 123, and the second end part 120 is bonded to the circuit board through the plurality of third binding points 133.

A plurality of signal wirings are disposed on one side of the chip on film area 103 adjacent to the first auxiliary area 101 and one side of the chip on film area 103 adjacent to the second auxiliary area 102. Each signal wiring 130 extends from the first end part 110 to the second end part 120, and when the chip on film assembly 10 is used, the display panel and the circuit board are electrically connected through the signal wirings 130. Specifically, on one side of the chip on film area 103 adjacent to the first auxiliary area 101, the plurality of signal wirings 130 are disposed along the first direction. On one side of the chip on film area 103 adjacent to the second auxiliary area 102, the plurality of signal wirings 130 are disposed along the first direction.

The embodiment of the present disclosure can prevent the signal wirings 130 broken by using the first auxiliary area 101 and the second auxiliary area 102 as buffer areas of the signal wirings 130. That is, a distance from the plurality of signal wirings 130 on the side adjacent to the first auxiliary area 101 to an edge of the substrate 100 is increased, which reduces the risk of disconnection of the plurality of signal wirings 130 on the side of the chip on film assembly 10 adjacent to the first auxiliary area 101 due to chip on film peeling off. Similarly, a distance from the plurality of signal wirings 130 on the side adjacent to the second auxiliary area 102 to an edge of the substrate 100 is increased, which reduces the risk of disconnection of the plurality of signal wirings 130 on the side of the chip on film assembly 10 adjacent to the second auxiliary area 102 due to chip on film peeling off.

In addition, an integrated chip 140, a plurality of first chip wirings 150, and a plurality of second chip wirings 160 are further disposed on the chip on film area. Each first chip wiring 150 extends from the first end part 110 to the integrated chip 140, and each second chip wiring 160 extends from the integrated chip 140 to the second end part 120. In the embodiment, the integrated chip 140, the plurality of first chip signal wirings 150, and the plurality of second chip wirings 160 are disposed between the plurality of signal wirings 130 on the side adjacent to the first auxiliary area 101 and the plurality of signal wirings 130 on the side adjacent to the second auxiliary area 102.

Because the integrated chip 140 is disposed on the chip on film area 103, the first chip wirings 150 and the second chip wirings 160 which are connected to the integrated chip 140 are also easily broken. Similarly, the first auxiliary area 101 and the second auxiliary area 102 disposed in the embodiment of the present disclosure can perform protection to the integrated chip 140, the first chip wirings 150, and the second chip wirings 160.

In an embodiment of the present disclosure, a width of the first auxiliary area 101 along the first direction and a width of the second auxiliary area 102 along the first direction range from 0.4 cm to 0.7 cm. In order to reduce the width of the chip on film assembly 10 in the first direction, through trial and error, by setting the width of the first auxiliary area 101 along the first direction and the width of the second auxiliary area 102 along the first direction between 0.4 cm to 0.7 cm, it can greatly reduce the risk of disconnection of the plurality of signal wirings 130 on the sides of the chip on film assembly 10 adjacent to the first auxiliary area 101 and the second auxiliary area 102 due to chip on film peeling off.

Further, in another embodiment, the width of the first auxiliary area 101 along the first direction is equal to the width of the second auxiliary area 102 along the first direction.

The embodiment of the present disclosure provides the chip on film assembly 10 by disposing the first auxiliary area 101 and the second auxiliary area 102 on both sides of the chip on film area 103 that prevents an edge of the chip on film assembly 10 to peel off and then to cause signal wirings 130 of the chip on film area 103 broken, thereby improving product yield and display quality.

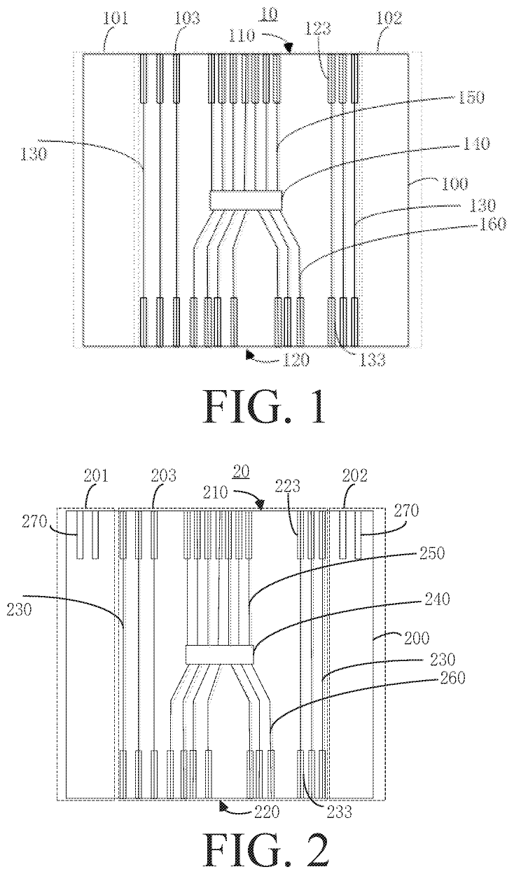

Referring to FIG. 2, FIG. 2 is a second schematic structural diagram of a chip on film assembly according to an embodiment of the present disclosure. Wherein, the difference of the chip on film assembly 20 shown in FIG. 2 from the chip on film assembly shown in FIG. 1 is that a first auxiliary area 201 and a second auxiliary area 202 of the chip on film assembly 20 are provided with a plurality of first binding points 270.

As shown in FIG. 2, the chip on film assembly 20 comprises a substrate 200, wherein the substrate 200 comprises the first auxiliary area 201, the second auxiliary area 202, and a chip on film area 203 disposed between the first auxiliary area 201 and the second auxiliary area 202, and the first auxiliary area 201, the chip on film area 203, and the second auxiliary area 202 are disposed in sequence along a first direction. It should be noted that, in the embodiment of the present disclosure, the first direction is not limited, it can be a horizontal direction, and it can be a vertical direction.

Wherein, the first auxiliary area 201 and the second auxiliary area 202 are provided with a plurality of first binding points 270, and the first binding points 270 are disposed adjacent to the first end part 210. The first binding points 270 are arranged at intervals along the first direction.

A material of the substrate 200 is a flexible material. Specifically, the substrate 200 is provided with a first end part 210 and a second end part 220 disposed opposite to the first end part 210. Wherein a second direction is disposed perpendicularly to the first direction. In an embodiment of the present disclosure, when the chip on film assembly 20 is used, the first end part 210 is bonded to the display panel (not shown in the figure) and is electrically connected to the display panel; the second end part 220 is bonded to the circuit board (not shown in the figure) and is electrically connected to the circuit board.

Wherein, the chip on film area 203 is provided with a plurality of second binding points 223 and third binding points 233, the second binding points 223 are disposed adjacent to the first end part 210, and the third binding points 233 are disposed adjacent to the second end part 220. In an embodiment of the present disclosure, when the chip on film assembly 20 is used, the first end part 210 is bonded to the display panel through the plurality of first binding points 270 and second binding points 223, and the second end part 220 is bonded to the circuit board through the plurality of third binding points 233. The first binding points 270 and the display panel are idly connected, the second binding points 223 and the display panel are electrically connected, and the third binding points 233 and the circuit board are electrically connected. It should be noted that, the first binding points 270 and the display panel are idly connected for protecting signal wirings 230 and strengthening connection stability between the chip on film assembly 20 and the display panel. That is, the first binding points 270 have no electric signals passing through.

A plurality of signal wirings 230 are disposed on one side of the chip on film area 203 adjacent to the first auxiliary area 201 and one side of the chip on film area 203 adjacent to the second auxiliary area 202. Each signal wiring 230 extends from the first end part 210 to the second end part 220, and when the chip on film assembly 20 is used, the display panel and the circuit board are electrically connected through the signal wirings 230. Specifically, on one side of the chip on film area 203 adjacent to the first auxiliary area 201, the plurality of signal wirings 230 are disposed along the first direction. On one side of the chip on film area 203 adjacent to the second auxiliary area 202, the plurality of signal wirings 230 are disposed along the first direction.

The embodiment of the present disclosure can prevent the signal wirings 230 broken by using the first auxiliary area 201 and the second auxiliary area 202 as buffer areas of the signal wirings 230. That is, a distance from the plurality of signal wirings 230 on the side adjacent to the first auxiliary area 201 to an edge of the substrate 200 is increased, which reduces the risk of disconnection of the plurality of signal wirings on the side of the chip on film assembly 20 adjacent to the first auxiliary area 201 due to chip on film peeling off. Similarly, a distance from the plurality of signal wirings 230 on the side adjacent to the second auxiliary area 202 to an edge of the substrate 200 is increased, which reduces the risk of disconnection of the plurality of signal wirings 230 on the side of the chip on film assembly 20 adjacent to the second auxiliary area 202 due to chip on film peeling off.

In addition, an integrated chip 240, a plurality of first chip wirings 250, and a plurality of second chip wirings 260 are further disposed on the chip on film area 203. Each first chip wiring 250 extends from the first end part 210 to the integrated chip 240, and each second chip wiring 260 extends from the integrated chip 240 to the second end part 220. In the embodiment, the integrated chip 240, the plurality of first chip signal wirings 250, and the plurality of second chip wirings 260 are disposed between the plurality of signal wirings 230 on the side adjacent to the first auxiliary area 201 and the plurality of signal wirings 230 on the side adjacent to the second auxiliary area 202.

Because the integrated chip 240 is disposed on the chip on film area 203, the first chip wirings 250 and the second chip wirings 260 which are connected to the integrated chip 240 are also easily broken. Similarly, the first auxiliary area 201 and the second auxiliary area 202 disposed in the embodiment of the present disclosure can perform protection to the integrated chip 240, the first chip wirings 250, and the second chip wirings 260.

The embodiment of the present disclosure provides the chip on film assembly 20 by disposing the first auxiliary area 201 and the second auxiliary area 202 on both sides of the chip on film area 203 that prevents an edge of the chip on film assembly 20 to peel off and then to cause signal wirings 230 of the chip on film area 203 broken, thereby improving product yield and display quality.

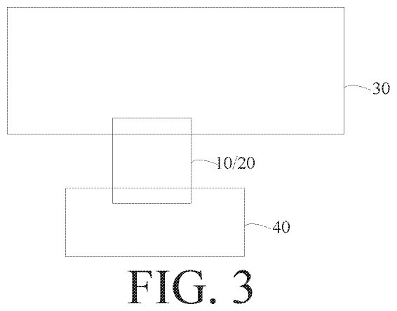

Referring to FIG. 3, FIG. 3 is a schematic structural diagram of a display panel assembly according to an embodiment of the present disclosure. As shown in FIG. 3, the present disclosure further provides a display panel assembly 30. The display panel assembly 30 comprises the above chip on film assembly 10/20, a circuit board 40, and a display panel 50. The chip on film assembly can be referred to the above description, which will not be iterated herein for the sake of conciseness.

The present disclosure has been described with a preferred embodiment thereof. The preferred embodiment is not intended to limit the present disclosure, and it is understood that many changes and modifications to the described embodiment can be carried out without departing from the scope and the spirit of the disclosure.

What is claimed is:

1. A chip on film assembly, comprising: a substrate, wherein the substrate comprises a first auxiliary area, a second auxiliary area, and a chip on film area disposed between the first auxiliary area and the second auxiliary area; the first auxiliary area, the chip on film area, and the second auxiliary area are disposed in sequence along a first direction;
wherein a plurality of signal wirings are disposed on one side of the chip on film area adjacent to the first auxiliary area and one side of the chip on film area that is adjacent to the second auxiliary area; the first auxiliary area and the second auxiliary area are used to prevent the signal wirings from breaking;
a width of the first auxiliary area along the first direction is equal to a width of the second auxiliary area along the first direction; and
a material of the substrate is a flexible material.

2. The chip on film assembly according to claim 1, wherein the substrate is provided with a first end part and a second end part opposite to the first end part in a second direction, and the first direction is perpendicular to the second direction; the first end part is bonded to a display panel and is electrically connected to the display panel; the second end part is bonded to a circuit board and is electrically connected to the circuit board.

3. The chip on film assembly according to claim 2, wherein the first auxiliary area and the second auxiliary area are provided with a plurality of first binding points, and the first binding points are disposed adjacent to the first end part and bonded to the display panel.

4. The chip on film assembly according to claim 3, wherein the first binding points are arranged at intervals along the first direction.

5. The chip on film assembly according to claim 3, wherein the chip on film area is provided with a plurality of second binding points and third binding points, the second binding points are disposed adjacent to the first end part and bonded to the display panel, and the third binding points are disposed adjacent to the second end part and bonded to the circuit board.

6. The chip on film assembly according to claim 5, wherein the first binding points and the display panel are idly connected, the second binding points and the display panel are electrically connected, and the third binding points and the circuit board are electrically connected.

7. The chip on film assembly according to claim 1, wherein the width of the first auxiliary area along the first direction and the width of the second auxiliary area along the first direction range from 0.4 cm to 0.7 cm.

8. A chip on film assembly, comprising: a substrate, wherein the substrate comprises a first auxiliary area, a second auxiliary area, and a chip on film area disposed between the first auxiliary area and the second auxiliary area; the first auxiliary area, the chip on film area, and the second auxiliary area are disposed in sequence along a first direction;
wherein a plurality of signal wirings are disposed on one side of the chip on film area adjacent to the first auxiliary area and one side of the chip on film area that is adjacent to the second auxiliary area; the first auxiliary area and the second auxiliary area are used to prevent the signal wirings from breaking.

9. The chip on film assembly according to claim 8, wherein the substrate is provided with a first end part and a second end part opposite to the first end part in a second direction, and the first direction is perpendicular to the second direction; the first end part is bonded to a display panel and is electrically connected to the display panel; the second end part is bonded to a circuit board and is electrically connected to the circuit board.

10. The chip on film assembly according to claim 9, wherein the first auxiliary area and the second auxiliary area are provided with a plurality of first binding points, and the first binding points are disposed adjacent to the first end part and bonded to the display panel.

11. The chip on film assembly according to claim 10, wherein the first binding points are arranged at intervals along the first direction.

12. The chip on film assembly according to claim 10, wherein the chip on film area is provided with a plurality of second binding points and third binding points, the second binding points are disposed adjacent to the first end part and bonded to the display panel, and the third binding points are disposed adjacent to the second end part and bonded to the circuit board.

13. The chip on film assembly according to claim 12, wherein the first binding points and the display panel are idly connected, the second binding points and the display panel are electrically connected, and the third binding points and the circuit board are electrically connected.

14. The chip on film assembly according to claim 8, wherein a width of the first auxiliary area along the first direction and a width of the second auxiliary area along the first direction range from 0.4 cm to 0.7 cm.

15. The chip on film assembly according to claim 8, wherein a width of the first auxiliary area along the first direction is equal to a width of the second auxiliary area along the first direction.

16. The chip on film assembly according to claim 8, wherein a material of the substrate is a flexible material.

17. A display panel assembly, comprising: a chip on film assembly, the chip on film assembly comprising a substrate, wherein the substrate comprises a first auxiliary area, a second auxiliary area, and a chip on film area disposed between the first auxiliary area and the second auxiliary area; the first auxiliary area, the chip on film area, and the second auxiliary area are disposed in sequence along a first direction;
wherein a plurality of signal wirings are disposed on one side of the chip on film area adjacent to the first auxiliary area and one side of the chip on film area that is adjacent to the second auxiliary area; the first auxiliary area and the second auxiliary area are used to prevent the signal wirings from breaking.

18. The display panel assembly according to claim 17, wherein the substrate is provided with a first end part and a second end part opposite to the first end part in a second direction, and the first direction is perpendicular to the second direction; the first end part is bonded to a display panel and is electrically connected to the display panel; the second end part is bonded to a circuit board and is electrically connected to the circuit board.

19. The display panel assembly according to claim 18, wherein the first auxiliary area and the second auxiliary area are provided with a plurality of first binding points, and the first binding points are disposed adjacent to the first end part and bonded to the display panel.

20. The display panel assembly according to claim 19, wherein the first binding points are arranged at intervals along the first direction.
